(19) United States
(12) Patent Application Publication
(10) Pub. No.: US 2022/0371103 A1
(43) Pub. Date: Nov. 24, 2022

(54) Board Drilling Apparatus, Drill Bit, and Method for Board Drilling Apparatus to Drill a Board

(71) Applicant: Telefonaktiebolaget LM Ericsson (publ), Stockholm (SE)

(72) Inventors: Pinghua Duan, Nanjing (CN); Xiaogang Song, Nanjing (CN); Qinqin Lu, Nanjing (CN)

(21) Appl. No.: 17/771,528

(22) PCT Filed: Oct. 25, 2019
(86) PCT No.: PCT/CN2019/113173

§ 371 Date: Apr. 25, 2022

(51) Int. Cl. B23B 35/00; B23B 27/14

(52) U.S. Cl. CPC B23B 35/00; B23B 27/14; B23B 2228/41; B23B 2228/10

(57) ABSTRACT

A board drilling apparatus, drill bit, and method for board drilling apparatus to drill a board. The board drilling apparatus (4) is configured to drill a board comprising at least a target conductive layer (13), an insulation layer, and a hole (3) covered with conductive material through at least part of the board in thickness, to remove at least part of the conductive material, the board drilling apparatus (4) comprising a drill bit (41) and a controller (43): the drill bit (41) comprising an insulation part (412) at least in center of end of the drill bit (41) and a conductive part (411) at least on edge of the end of the drill bit (41), arranged to enable only the insulation part (412) to be in touch with the conductive material of the hole (3) when the board drilling apparatus (4) is drilling the board, and arranged to enable the conductive part to get in touch with the target conductive layer (13) once the conductive material on the way to the target conductive layer (13) has just been removed; and the controller (43) configured to stop drilling when receiving an electrical signal occurred in response to the drill bit touching the target conductive layer of the board.

### TECHNICAL FIELD

The present invention relates to the field of board manufacturing technologies, and in particular, to a board drilling apparatus, drill bit, and method for board drilling apparatus to drill a board.

### BACKGROUND

This section is intended to provide a background to the various embodiments of the technology described in this disclosure. The description in this section may include concepts that could be pursued, but are not necessarily ones that have been previously conceived or pursued. Therefore, unless otherwise indicated herein, what is described in this section is not prior art to the description and/or claims of this disclosure and is not admitted to be prior art by the mere inclusion in this section.

Multilayer circuit boards and/or wiring boards are well known in the art. The multilayer circuit boards are formed with a number of signal layers (conductive layers) which are arranged in a predetermined pattern. The signal layers are insulated from each other by dielectric layers (insulation layers). Thus, the multilayer circuit board is formed from interleaved (e.g., alternating) signal layers and dielectric layers.

Plated holes or “vias” are formed through the multilayer circuit board to connect one signal layer to another signal layer. The plated holes typically extend from one main side of the multilayer circuit board to an opposite side of the multilayer circuit board. In some instances, the plated holes or vias include a “stub portion” which extends away from the signal layer toward one of the sides of the multilayer circuit board. In some circumstances, it is desirable to remove the stub portion to enhance the signal to noise ratio in electronic systems that utilize high-speed signals. The smaller the stub portion the better the signal quality.

In the past, the stub portion of the plated holes is removed in a process referred to as “back drilling”. In the back drilling process, the stub portion of the plated hole is removed by drilling the stub portion to a predetermined depth. However, in practice the thicknesses of the various layers in the multilayer circuit boards are not uniform, and the depths of the signal layers within the multilayer circuit boards vary, which often changes the amount of the stub portion which needs to be removed. Drilling too deeply will disconnect the signal layer from the plated hole, or leave an unreliable connection; not drilling deep enough decreases the signal to noise ratio.

### SUMMARY

It is therefore objects of the present disclosure to address or at least partially address the above mentioned problems.

According to one embodiment of the disclosure, there is provided a board drilling apparatus configured to drill a board comprising at least a target conductive layer, an insulation layer, and a hole covered with conductive material through at least part of the board in thickness, to remove at least part of the conductive material, the board drilling apparatus comprising a drill bit and a controller: the drill bit comprising an insulation part at least in center of end of the drill bit and a conductive part at least on edge of the end of the drill bit, arranged to enable only the insulation part to be in touch with the conductive material of the hole when the board drilling apparatus is drilling the board, and arranged to enable the conductive part to get in touch with the target conductive layer once the conductive material on the way to the target conductive layer has just been removed; and the controller configured to stop drilling when receiving an electrical signal occurred in response to the drill bit touching the target conductive layer of the board.

According to another embodiment of the disclosure, there is provided a drill bit of a board drilling apparatus configured to drill a board comprising at least a target conductive layer, an insulation layer, and a hole covered with conductive material through at least part of the board in thickness, to remove at least part of the conductive material: the drill bit comprising an insulation part at least in center of end of the drill bit and a conductive part at least on edge of the end of the drill bit, arranged to enable only the insulation part to be in touch with the conductive material of the hole when the board drilling apparatus is drilling the board, and arranged to enable the conductive part to get in touch with the target conductive layer once the conductive material on the way to the target conductive layer has just been removed.

According to third embodiment of the disclosure, there is provided a method for a board drilling apparatus to drill a board comprising at least a target conductive layer, an insulation layer, and a hole covered with conductive material through at least part of the board in thickness, to remove at least part of the conductive material, the board drilling apparatus comprising a drill bit and a controller, the drill bit comprising an insulation part at least in center of end of the drill bit and a conductive part at least on edge of the end of the drill bit, arranged to enable only the insulation part to be in touch with the conductive material of the hole when the board drilling apparatus is drilling the board, and arranged to enable the conductive part to get in touch with the target conductive layer once the conductive material on the way to the target conductive layer has just been removed, the method comprising: aligning 506 the insulation part to the conductive material of the hole: starting 508 drilling the board along the hole to remove the conductive material; and stopping 50 drilling by the controller when it receives an electrical signal occurred in response to the drill bit touching the target conductive layer of the board.

The embodiments of the present invention, as a whole or by scenario, can ensure a proper drilling depth that will neither drills too much, nor leave a stub portion in the hole, regardless of how the depths of the conductive layers and the insulations layers vary. This is particular advantageous in electronic systems that utilize high-speed signals, where the board is a circuit board, such as a multilayer printed circuit board, as the signal to noise ratio will be greatly enhanced as a result.

### BRIEF DESCRIPTION OF THE DRAWINGS

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and details through use of the accompanying drawings.

FIG. 1 illustrates a schematic view of a board drilling apparatus aligning to a hole of a board to be drilled according to some references.

FIGS. 2-3 illustrate schematic views of the board after drilling according to some references.

FIG. 4 illustrates a schematic view of signals occurred when the board drilling apparatus are drilling the board according to some references.

FIG. 5 illustrates a schematic view of structure of a board drilling apparatus according to an embodiment of the present invention.

FIG. 6 illustrates a schematic view of structure of a board drilling apparatus according to another embodiment of the present invention.

FIG. 7 illustrates a schematic top view of a drill bit of a board drilling apparatus according to an embodiment of the present invention.

FIG. 8 illustrates a schematic top view of a drill bit of a board drilling apparatus according to another embodiment of the present invention.

FIG. 9 illustrates a schematic view of signals occurred when the board drilling apparatus are drilling the board according to an embodiment of the present invention.

FIG. 10 illustrates a schematic view of a kind of board to be drilled.

FIG. 11 illustrates a schematic view of signals occurred when the board drilling apparatus are drilling the board of FIG. 10 according to an embodiment of the present invention.

FIG. 12 illustrates a schematic view of another kind of board to be drilled.

FIG. 13 illustrates a schematic view of signals occurred when the board drilling apparatus are drilling the board of FIG. 12 according to an embodiment of the present invention.

FIG. 14 illustrates a schematic view of the board after drilling according to an embodiment of the present invention.

FIG. 15 illustrates a flowchart of a method for a board drilling apparatus to drill a board according to an embodiment of the present invention.

FIG. 16 schematically illustrates an embodiment of a controller of a board drilling apparatus according to an embodiment of the present invention.

### DETAILED DESCRIPTION

Embodiments herein will be described in detail hereinafter with reference to the accompanying drawings, in which embodiments are shown. These embodiments herein may, however, be embodied in many different forms and should not be construed as being limited to the embodiments set forth herein. The elements of the drawings are not necessarily to scale relative to each other. Like numbers refer to like elements throughout.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood. For example, “board” refers to a commonly understood board, rather than only “circuit board”, though “circuit board” is used as an example in embodiments of the invention.

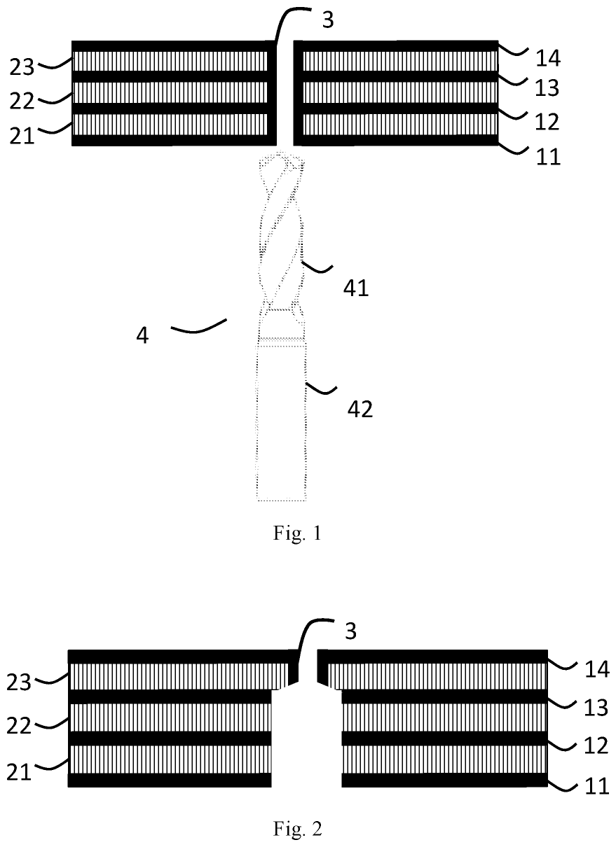

FIG. 1 illustrates a schematic view of a board drilling apparatus aligning to a hole of a board to be drilled according to some references. An example of the board is a printed circuit board, formed with a number of signal layers—conductive layers 11, 12, 13 and 14—which are arranged in a substantially parallel pattern. The conductive layers are insulated from each other by dielectric layers—insulation layers 21, 22 and 23 respectively. As shown in FIG. 1, the insulation layers and the conductive layers are alternating, in some other examples, there could be more than one insulations layers between two conductive layers. The board further comprises a hole 3 with its axis perpendicular to the layers, covered (such plated) with conductive material. As shown in FIG. 1, the hole 3 extends from the conductive layer 11 to the conductive layer 14, i.e., all through the board in thickness. In some other examples, the hole only extends through some of the layers, i.e., through part of the board in thickness. In some further examples, the hole may be not perpendicular to the layers, but with an angle other than 90 degrees to the layers. A board drilling apparatus 4 comprises a drill bit 41 and a base 42, and is used to drill the board to remove at least part of the conductive material covering the hole, i.e., the stub portion. The stub portion of the plated hole is removed by drilling the stub portion to a target conductive layer, say layer 13.

U.S. Pat. No. 9,827,616B2 discloses a drilling method that requires predetermining of depth of the target layer, including the following steps: performing a drilling motion from an initial location, and generating a first electrical signal when coming into contact with a first conductive layer of the PCB, determining a first conductive location according to the first electrical signal, and obtaining first Z-coordinate information; continuing to perform the drilling motion after drilling through the first conductive layer, and generating a second electrical signal when coming into contact with a second conductive layer, determining a second conductive location according to the second electrical signal, and obtaining second Z-coordinate information; continuing to perform the drilling motion and drilling through the PCB to obtain a through hole; and performing back drilling in the location of the through hole according to a preset depth, and the preset depth is a medium thickness between the second conductive layer and the first conductive layer plus a compensation depth.

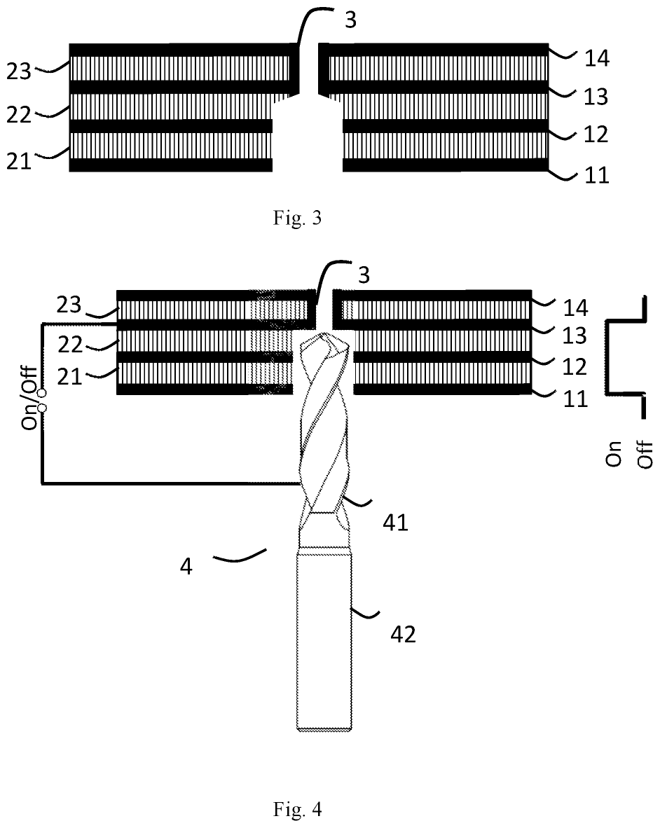

However, in some references, the depth of the target layer in the board is not uniform and varies, which often changes the amount of the stub portion that needs to be removed. Drilling too deeply will disconnect the signal layer from the hole, as shown in FIG. 2, or leave an unreliable connection; not drilling deep enough, as shown in FIG. 3 decreases the signal to noise ratio.

Besides, In the method of U.S. Pat. No. 9,827,616B2, the board has to be designed specifically for generating different electrical signals for determining different Z-coordinate information, which is not universally applicable.

In some references, the drill bit 41 is wholly conductive, for example, it is made of steel. If we connect the target conductive layer 13 with the drill bit 41 via a wire as shown in FIG. 4, an electrical signal will occur as the drill bit 41 gets in touch with the conductive material covering the hole 3, until it drills through the conductive layer 13. Such an electrical signal would not help determine the desired drilling depth.

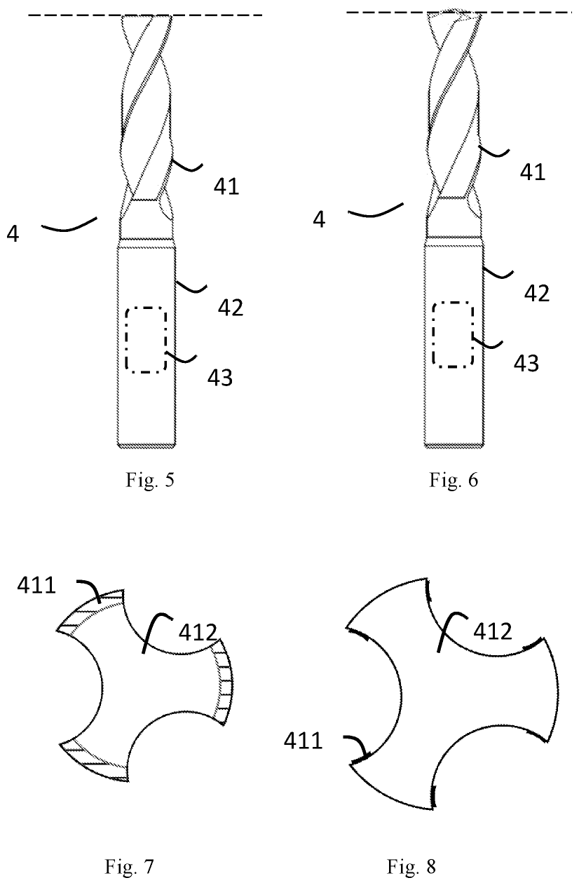

FIGS. 5-8 illustrate a board drilling apparatus 4 schematically according to embodiments of the present invention. The board drilling apparatus 4 comprises a drill bit 41, a base 42, and a controller 43, for example hosted within the base 42.

FIGS. 7-8 illustrate schematic top views of the drill bit of the board drilling apparatus according to embodiments of the present invention. As shown in FIGS. 7-8, the drill bit 41 comprises an insulation part 412 at least in center of end of the drill bit 41 and a conductive part 411 at least on edge of the end of the drill bit 41. The insulation part 412 and the conductive part 411 are arranged to enable only the insulation part 412 to be in touch with the conductive material of the hole 3 when the board drilling apparatus 4 is drilling the board, and arranged to enable the conductive part 411 to get in touch with the target conductive layer 13 once the conductive material on the way to the target conductive layer 13 has just been removed. Under the above principles, variations can be made to the drill bit, such as in one example, the conductive part 411 covers cutting edge of the end of the drill bit 41, as shown by the shadow areas in FIG. 7, or only covers part of it, and in another example, the conductive part 411 covers groove of the end of the drill bit 41, or only covers part of it, as shown by the bolded lines in FIG. 8. To avoid the conductive part 411 to get in touch with the conductive material of the same hole 3, apparently, the drill bit 4 with the structure of FIG. 8 may require a larger size in cross section than the drill bit 4 with the structure of FIG. 7. In a further example, the drill bit 41, except the insulation part 412 in center of end of the drill bit 41, is the conductive part 411.

In one embodiment as shown in FIG. 5, the center of the end of the drill bit where the insulation part lies and the edge of the end of the drill bit wherein the conductive part lies are flush along a certain direction, so as to get to the same depth along a direction, for example, along the axis of the drill bit. In another embodiment as shown in FIG. 6, the center of the end of the drill bit where the insulation part lies and the edge of the end of the drill bit wherein the conductive part lies are flush along a certain direction, so as to get to the same depth along the direction, for example, along the axis of the drill bit, but there is a slight tip in the center of the end of the drill bit, which could be used to align to the hole 3 of the board, but not get in touch with the conductive material of the hole 3. Preferably, the tip could be simply made of the same material as the insulation part 412. However, as the tip is too small to get in touch with the conductive material of the hole 3 when the drill bit 41 is aligned to the hole 3, other material as appropriate, including conductive material is also possible.

In an embodiment of the present invention, the insulation part 411 is made of material comprising one or more of the following: diamond material or zirconium dioxide.

In an embodiment of the present invention, the conductive part 412 is made by metal plating.

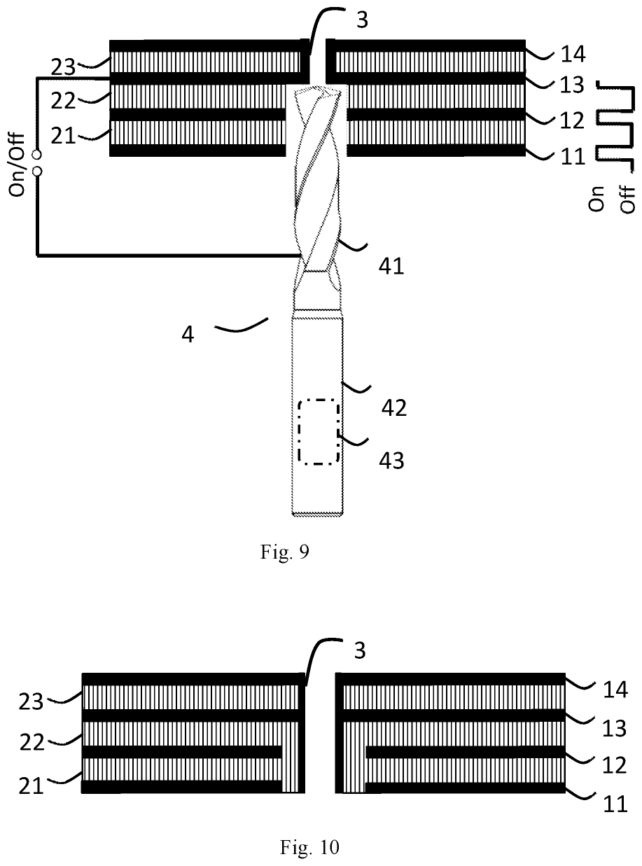

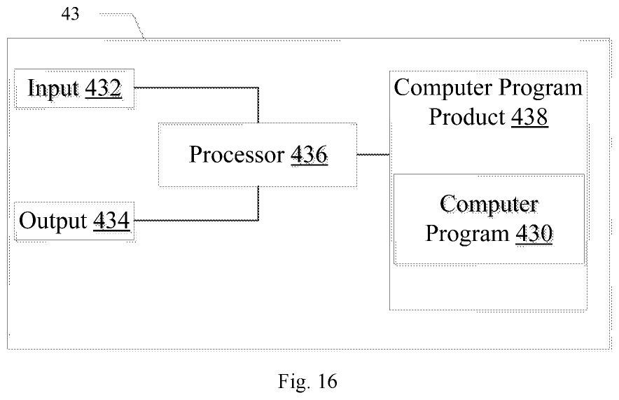

The controller 43 is configured to stop drilling when receiving an electrical signal occurred in response to the drill bit 41 touching the target conductive layer 13 of the board. The electrical signal could be conducted all the way to the controller 43 from the conductive part 411 of the drill bit 41, or could be transmitted wirelessly to the controller 43. Some details of the electrical signals will be described below with reference to FIGS. 9, 11 and 13, and structure of the controller 43 will be described below with reference to FIG. 16.

The target conductive layer 13 is selected from the conductive layers 11, 12, 13, and 14, each of which corresponds to a respective electrical signal occurred in response to the drill bit 41 touching it. It is noted that embodiments herein are described with the conductive layer 13 selected as the target layer, even though conductive layers 12, 14, etc. could also be selected as the target layer. When there is a further insulation layer below the conductive layer 11 and the hole is through it, the conductive layer 11 may also be selected as the target conductive layer.

FIG. 9 illustrates a schematic view of signals occurred when the board drilling apparatus are drilling the board according to an embodiment of the present invention. In an example, the board is a circuit board that looks like the one in FIG. 1, and again, suppose the conductive layer 13 is selected as the target conductive layer. The target conductive layer 13 is electrically coupled to the conductive part 411 of the drill bit 41 from a point away from the hole 3 via for example a wire. As the conductive part 411 of the drill bit 41 gets in touch with the conductive layer 11 after the drill bit 41 has been aligned to the hole 3, part of the target conductive layer 13, the wire, part of the conductive part 411 of the drill bit 41, part of the conductive layer 11, and part of the conductive material of the hole 3 will form a loop, and then a first electrical signal is generated, as shown by a pulse beside the conductive layer 11 in FIG. 9. As the first electrical signal does not correspond to the target conductive layer 13, the controller will not take any action.

It is noted that in the process of drilling, the conductive part 411 of the drill bit 41 will not get in touch with the conductive material of the hole 3, but only the insulation part 412 of the drill bit 41 will be in touch with the conductive material of the hole 3.

Once the conductive layer 11 is drilled through, the loop is open as the conductive layer 11 is no longer connected with the conductive material of the hole 3 and the first electrical signal terminates. Then as the conductive part 411 of the drill bit 41 gets in touch with the conductive layer 12, part of the target conductive layer 13, the wire, part of the conductive part 411 of the drill bit 41, part of the conductive layer 12, and part of the conductive material of the hole 3 will form a loop, and then a second electrical signal is generated, as shown by a pulse beside the conductive layer 12 in FIG. 9. As the second electrical signal does not correspond to the target conductive layer 13, the controller will not take any action.

Similarly, once the conductive layer 12 is drilled through, the loop is open again as the conductive layer 12 is no longer connected with the conductive material of the hole 3 and the second electrical signal terminates. Then as the conductive part 411 of the drill bit 41 gets in touch with the conductive layer 13, part of the target conductive layer 13, the wire and part of the conductive part 411 of the drill bit 41 will form a loop, and then a third electrical signal is generated, as shown by a pulse beside the conductive layer 12 in FIG. 9. As the third electrical signal corresponds to the target conductive layer 13, the controller 43 determines to stop drilling when receiving the third electrical signal.

In this embodiment, the first, second and third electrical signals may be the same, and the controller 43 recognizes the electrical signal corresponding to the target conductive layer 13 by counting electrical signal numbers. However, the present invention is not limited to this embodiment, and a person skilled in the art would know that variations could be made regarding how the controller 43 recognizes the electrical signal corresponding to the target conductive layer 13.

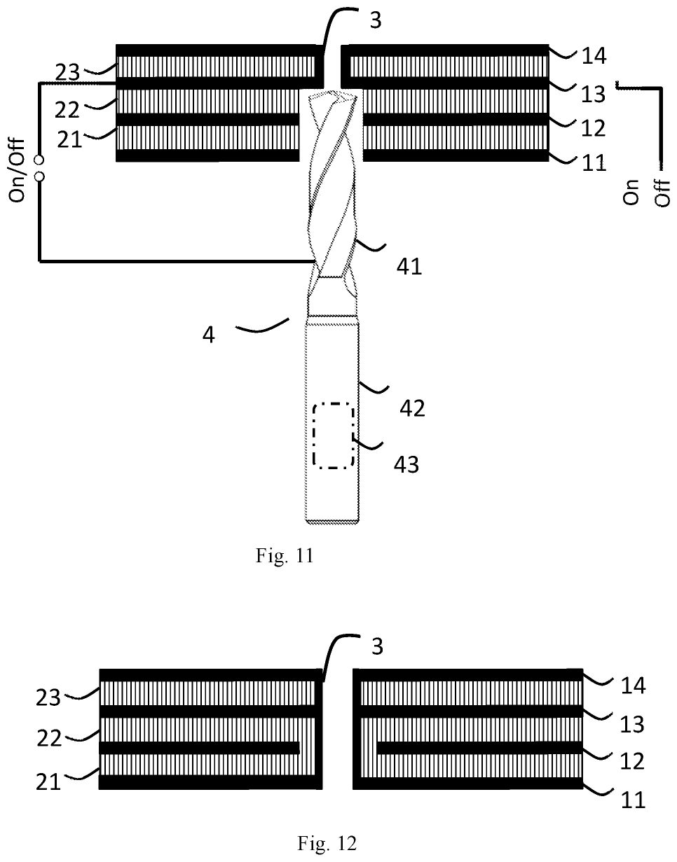

FIG. 10 illustrates a schematic view of a kind of board to be drilled, and FIG. 11 illustrates a schematic view of signals occurred when the board drilling apparatus are drilling the board of FIG. 10 according to an embodiment of the present invention. In FIG. 10, each of the conductive layers 11 and 12 is a distance away from the hole that the drill bit 41 will not get in touch with them in the process of drilling the hole 3. Again, In an example, the board is a circuit board and suppose the conductive layer 13 is selected as the target conductive layer. The target conductive layer 13 is electrically coupled to the conductive part 411 of the drill bit 41 from a point away from the hole 3 via for example a wire. As the conductive part 411 of the drill bit 41 gets in touch with the target conductive layer 11 after the conductive material of the hole 3 under the target conductive layer 13 has been drilled, part of the target conductive layer 13, the wire and part of the conductive part 411 of the drill bit 41 will form a loop, and then a first electrical signal is generated, as shown by a pulse beside the target conductive layer 13 in FIG. 11. As the first electrical signal corresponds to the target conductive layer 13, the controller 43 determines to stop drilling when receiving the first electrical signal.

Before that, as the conductive part 411 of the drill bit 41 will not get in touch with the conductive material of the hole 3, but only the insulation part 412 of the drill bit 41 will be in touch with the conductive material of the hole 3, there is no loop formed and no signal received by the controller 43.

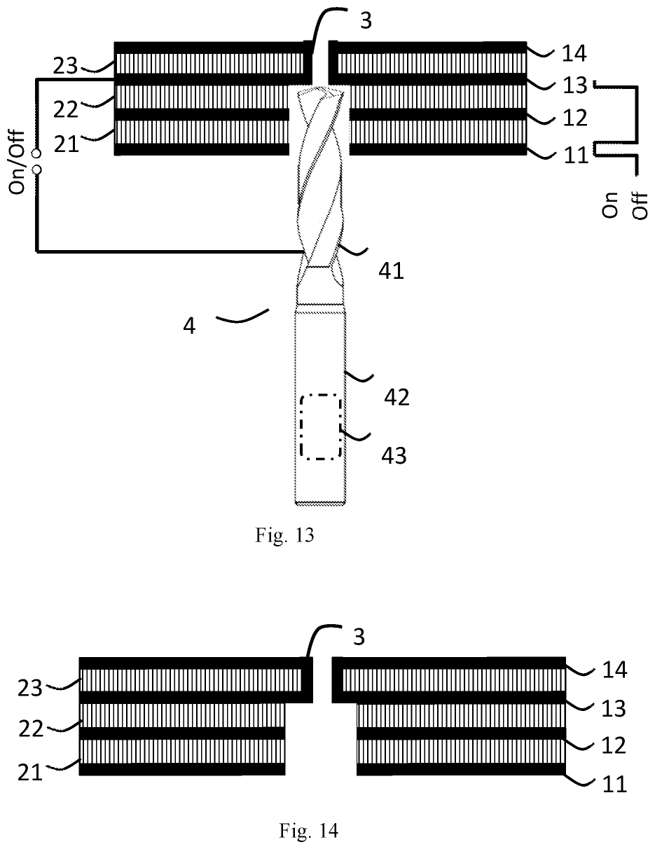

FIG. 12 illustrates a schematic view of another kind of board to be drilled, and FIG. 13 illustrates a schematic view of signals occurred when the board drilling apparatus are drilling the board of FIG. 12 according to an embodiment of the present invention. In FIG. 12, the conductive layer 11 12 is a distance away from the hole that the drill bit 41 will not get in touch with it in the process of drilling. Again, in an example, the board is a circuit board and suppose the conductive layer 13 is selected as the target conductive layer. The target conductive layer 13 is electrically coupled to the conductive part 411 of the drill bit 41 from a point away from the hole 3 via for example a wire. As the conductive part 411 of the drill bit 41 gets in touch with the conductive layer 11 after the drill bit 41 has been aligned to the hole 3, part of the target conductive layer 13, the wire, part of the conductive part 411 of the drill bit 41, part of the conductive layer 11, and part of the conductive material of the hole 3 will form a loop, and then a first electrical signal is generated, as shown by a pulse beside the conductive layer 11 in FIG. 13. As the first electrical signal does not correspond to the target conductive layer 13, the controller will not take any action.

It is noted that in the process of drilling, the conductive part 411 of the drill bit 41 will not get in touch with the conductive material of the hole 3, but only the insulation part 412 of the drill bit 41 will be in touch with the conductive material of the hole 3.

Once the conductive layer 11 is drilled through, the loop is open as the conductive layer 11 is no longer connected with the conductive material of the hole 3 and the first electrical signal terminates. Then as the conductive part 411 of the drill bit 41 gets in touch with the conductive layer 13, part of the target conductive layer 13, the wire and part of the conductive part 411 of the drill bit 41 will form a loop, and then a second electrical signal is generated, as shown by a pulse beside the conductive layer 13 in FIG. 13. As the third electrical signal corresponds to the target conductive layer 13, the controller 43 determines to stop drilling when receiving the third electrical signal. Between the first signal and the second signal, as the conductive part 411 of the drill bit 41 will not get in touch with the conductive material of the hole 3, but only the insulation part 412 of the drill bit 41 will be in touch with the conductive material of the hole 3, there is no loop formulated and no signal received by the controller 43.

In this embodiment, the first and second electrical signals may be the same, and the controller 43 recognizes the electrical signal corresponding to the target conductive layer 13 by counting electrical signal numbers. However, the present invention is not limited to this embodiment, and a person skilled in the art would know that variations could be made regarding how the controller 43 recognizes the electrical signal corresponding to the target conductive layer 13.

Embodiments of the present invention can ensure a proper drilling depth that will neither disconnect the target conductive layer from the hole, nor leave a stub portion in the hole, regardless of how the depths of the conductive layers and the insulations layers vary, as shown by a schematic view of the board after drilling according to an embodiment of the present invention in FIG. 14. No predetermined depth is required. This is particular advantageous in electronic systems that utilize high-speed signals, where the board is a circuit board, such as a multilayer printed circuit board, as the signal to noise ratio will be greatly enhanced as a result.

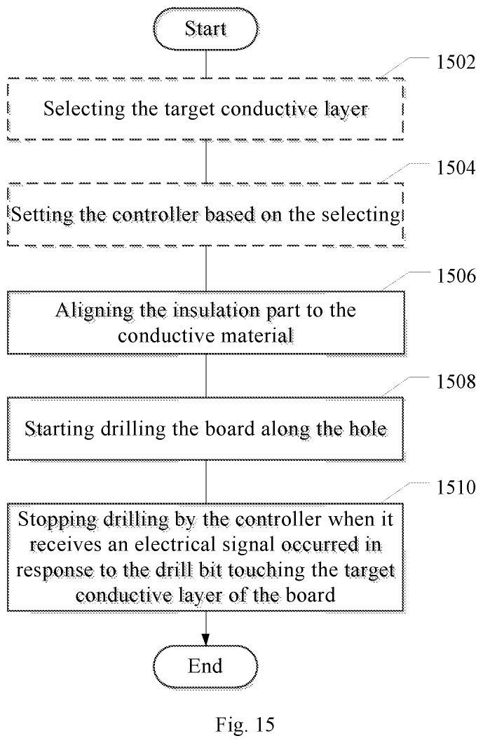

FIG. 15 illustrates a flowchart of a method for a board drilling apparatus to drill a board according to an embodiment of the present invention. The board drilling apparatus is one of those shown in FIG. 5-8 as described above, i.e., it comprises a drill bit 41 and a controller 43, the drill bit 41 comprises an insulation part 412 at least in center of end of the drill bit 41 and a conductive part 411 at least on edge of the end of the drill bit 41, arranged to enable only the insulation part 412 to be in touch with the conductive material of the hole 3 when the board drilling apparatus 4 is drilling the board, and arranged to enable the conductive part 411 to get in touch with the target conductive layer 13 once the conductive material on the way to the target conductive layer 13 has just been removed. In an example, the board is a circuit board.

In an embodiment, the method starts at step 1506, wherein the drill bit 41 of the board drilling apparatus 4 is aligned to the hole, which requires the insulation part 412 of the drill bit 41 being aligned to the conductive material of the hole 3. In this way, only the insulation part 412 is in touch with the conductive material of the hole 3. It will be easier for the board drilling apparatus of FIG. 6 to perform this step, as the tip in the center of the end can be used as a reference point to align to the hole 3.

Then at step 1508, drilling the board along the hole 3, to remove the conductive material of the hole 3.

Then at step 1510, when the controller 43 receives an electrical signal occurred in response to the drill bit 41 touching the target conductive layer 13 of the board, the controller 43 stops drilling.

Generally, a board may comprise multiple conductive layers as shown in FIGS. 1, 10 and 12, and the target conductive layer could be any of layers 11, 12 and 13 in FIG. 1, or layers 13 and 14 in FIG. 10, or layers 13 and 14 in FIG. 12, i.e., the target conduct layer could be selected from them, as long as a respective electrical signal will occur in response to the drill bit 41 touching any of them. FIGS. 9, 11 and 13 shows an example to generate an electrical signal in response to the drill bit 41 touching the target conductive layer, however, the present invention is not limited to such an example and other variations could be included, such as connecting the conductive part 411 of the drill bit 41 to the ground, then the signals from the target conductive layer 13 may flow to the conductive part 411. Therefore, before step 1506, there could be a step 1502, wherein the target conductive layer 13 is selected from several conductive layers of the board, such as layers 11, 12 and 13 in FIG. 1, or layers 13 and 14 in FIG. 10, or layers 13 and 14 in FIG. 12.

As each of the several conductive layers corresponds to a respective electrical signal, and the controller 43 is required to recognize it, a controller setting step 1504 is needed before step 1508, to enable it to recognize the electrical signal of the target conductive layer, based on the selection of step 1502. For example, in FIG. 9, the electrical signal of the target conductive layer 13 is the third signal the controller receives, and in FIG. 11, the electrical signal of the target conductive layer 13 is the first signal the controller receives, and in FIG. 13, the electrical signal of the target conductive layer 13 is the second signal the controller receives.

FIG. 16 schematically illustrates an embodiment of the controller 43 of the board drilling apparatus 4 according to an embodiment of the present invention. Comprised in the controller 43 are here a processor 436, e.g., with a Digital Signal Processor (DSP). The processor 436 may be a single unit or a plurality of units to perform different actions of procedures described herein. The controller 43 may also comprise an input unit 432 for receiving signals from other entities, such as signals for setting the controller 43 to enable it to recognize the electrical signal of the target conductive layer based on the selection of step 1502, or electrical signals received from the drill bit. The controller 43 may also comprise an output unit 434 for providing signals to other entities, such as signals to stop drilling. The input unit 432 and the output unit 434 may be arranged as an integrated entity, and may be enabled for any of wired communications, wireless communications such as Blue Tooth, NFC etc. or both.

Furthermore, the controller 43 comprises at least one computer program product 438, in the form of a non-volatile or volatile memory, e.g., an Electrically Erasable Programmable Read-Only Memory (EEPROM), a flash memory and a hard drive. The computer program product 438 comprises a computer program 430, which comprises code/computer readable instructions, which when executed by the processor 436 in the controller 43, causes the controller 43 to perform actions, e.g., adapting to the setting for it to recognize the electrical signal of the target conductive layer, determining whether the received electrical signal corresponds to the target conductive layer, sending signals to stop drilling, etc..

The processor 436 may be a single CPU (Central processing unit), but could also comprise two or more processing units. For example, the processor 436 may include general purpose microprocessors, instruction set processors and/or related chips sets and/or special purpose microprocessors such as Application Specific Integrated Circuit (ASICs). The processor 436 may also comprise board memory for caching purposes. The computer program 430 may be carried by a computer program product 438 connected to the processor 436. The computer program product may comprise a computer readable medium on which the computer program is stored. For example, the computer program product may be a flash memory, a Random-access memory (RAM), a Read-Only Memory (ROM), or an EEPROM, and the computer program modules to perform different actions described above could in alternative embodiments be distributed on different computer program products in the form of memories within the controller 43.

The embodiments of the present invention, as a whole or by scenario, can ensure a proper drilling depth that will neither drills too much, nor leave a stub portion in the hole, regardless of how the depths of the conductive layers and the insulations layers vary. No predetermined depth is required. This is particular advantageous in electronic systems that utilize high-speed signals, where the board is a circuit board, such as a multilayer printed circuit board, as the signal to noise ratio will be greatly enhanced as a result.

While the embodiments have been illustrated and described herein, it will be understood by those skilled in the art that various changes and modifications may be made, and equivalents may be substituted for elements thereof without departing from the true scope of the present technology. In addition, many modifications may be made to adapt to a particular situation and the teaching herein without departing from its central scope. Therefore it is intended that the present embodiments not be limited to the particular embodiment disclosed as the best mode contemplated for carrying out the present technology, but that the present embodiments include all embodiments falling within the scope of the appended claims.

1-17. (canceled)

18. A board drilling apparatus configured to drill a board comprising at least a target conductive layer, an insulation layer, and a hole covered with conductive material through at least part of the board in thickness, to remove at least part of the conductive material, the board drilling apparatus comprising a drill bit and a controller:
the drill bit comprising an insulation part at least in a center of an end of the drill bit and a conductive part at least on an edge of the end of the drill bit, arranged to enable only the insulation part to be in touch with the conductive material of the hole when the board drilling apparatus is drilling the board, and arranged to enable the conductive part to get in touch with the target conductive layer once the conductive material on the way to the target conductive layer has just been removed; and
the controller configured to stop drilling when receiving an electrical signal occurred in response to the drill bit touching the target conductive layer of the board.

19. The board drilling apparatus of claim 18, wherein the conductive part covers at least part of a cutting edge of the end of the drill bit.

20. The board drilling apparatus of claim 18, wherein the conductive part covers at least part of a groove of the end of the drill bit.

21. The board drilling apparatus of claim 18, wherein the board comprises muliple conductive layers in parallel, each of which gets in touch with the conductive part of the drill bit and generates a respective electrical signal as the drill bit drills that conductive layer, wherein the target conductive layer is selected from the multiple conductive layers.

22. The board drilling apparatus of claim 18, further comprising a tip in the center of the end of the drill bit, which is small enough to fit the hole without getting in touch with the conductive material of the hole when the drill bit is aligned to the hole.

23. The board drilling apparatus of claim 18, wherein the insulation part is made of material comprising one or more of the following: diamond material or zirconium dioxide.

24. The board drilling apparatus of claim 18, wherein the insulation part is in a center of the end of the drill bit and the rest of the drill bit is the conductive part.

25. The board drilling apparatus of claim 18, wherein the board is a circuit board.

26. A drill bit of a board drilling apparatus configured to drill a board comprising at least a target conductive layer, an insulation layer, and a hole covered with conductive material through at least part of the board in thickness, to remove at least part of the conductive material, wherein the drill bit comprises:
an insulation part at least in a center of an end of the drill bit and a conductive part at least on an edge of the end of the drill bit, arranged to enable only the insulation part to be in touch with the conductive material of the hole when the board drilling apparatus is drilling the board, and arranged to enable the conductive part to get in touch with the target conductive layer once the conductive material on the way to the target conductive layer has just been removed.

27. The drill bit of claim 26, wherein the conductive part covers at least part of a cutting edge of the end of the drill bit.

28. The drill bit of claim 26, wherein the conductive part covers at least part of a groove of the end of the drill bit.

29. The drill bit of claim 26, further comprising a tip in the center of the end of the drill bit, which is small enough to fit the hole without getting in touch with the conductive material of the hole when the drill bit is aligned to the hole.

30. The drill bit of claim 26, wherein the insulation part is made of material comprising one or more of the following: diamond material or zirconium dioxide.

31. The drill bit of claim 26, wherein the drill bit is configured to drill a circuit board.

32. A method for a board drilling apparatus to drill a board comprising at least a target conductive layer, an insulation layer, and a hole covered with conductive material through at least part of the board in thickness, to remove at least part of the conductive material, the board drilling apparatus comprising a drill bit and a controller, the drill bit comprising an insulation part at least in a center of an end of the drill bit and a conductive part at least on an edge of the end of the drill bit, arranged to enable only the insulation part to be in touch with the conductive material of the hole when the board drilling apparatus is drilling the board, and arranged to enable the conductive part to get in touch with the target conductive layer once the conductive material on the way to the target conductive layer has just been removed, the method comprising:
aligning the insulation part to the conductive material of the hole;
starting drilling the board along the hole to remove the conductive material; and
stopping drilling by the controller when the controller receives an electrical signal occurred in response to the drill bit touching the target conductive layer of the board.

33. The method of claim 32, wherein the board comprises multiple conductive layers parallel to the target conductive layer, each of which gets in touch with the drill bit and generates a respective electrical signal as the drill bit drills that conductive layer, the method further comprising:
selecting the target conductive layer from the multiple conductive layers of the board before starting drilling; and
setting the controller before starting drilling to enable the controller to recognize the respective electrical signal corresponding to the target conductive layer based on the selecting.

34. The method of claim 32, wherein the board is a circuit board.
